(19) United States
(12) Patent Application Publication
(10) Pub. No.: US 2021/0141418 A1
(43) Pub. Date: May 13, 2021

(54) DISPLAY DEVICE

(71) Applicant: Samsung Display Co., Ltd., Yongin-Si (KR)

(72) Inventor: MYUNGAN MIN, Cheonan-si (KR)

(21) Appl. No.: 16/988,910

(22) Filed: Aug. 10, 2020

(30) Foreign Application Priority Data
Nov. 7, 2019 (KR) 10-2019-0141853

(51) Int. Cl. G06F 1/16; H05K 5/00

(52) U.S. Cl. CPC G06F 1/1616; H05K 5/0017; G06F 1/1656; G06F 1/1626

(57) ABSTRACT

A display device includes a display module in which a folding area, a first non-folding area, and a second non-folding area are defined, and a cover panel coupled to a surface of the display module. The cover panel includes a first support plate which supports the first non-folding area, a second support plate spaced apart from the first support plate and which supports the second non-folding area, and an adhesive layer disposed between the display module and first and second support plates and which couples the first and second support plates to the display module. The adhesive layer has a first surface in contact with the first and second support plates, the first surface has a pattern area in which an uneven pattern is formed, and the pattern area overlaps the folding area.

This application claims priority to Korean Patent Application No. 10-2019-0141853, filed on Nov. 7, 2019, and all the benefits accruing therefrom under 35 U.S.C. § 119, the content of which in its entirety is herein incorporated by reference.

### BACKGROUND

### 1. Field

The disclosure herein relates to a display device, and more particularly, to a foldable display device.

### 2. Description of the Related Art

Electronic apparatuses, such as televisions, mobile phones, tablet computers, navigation devices and game consoles, may include a display device for providing information.

Recently, with the technological development for the display device, various types of display device have been developed. For example, flexible display devices, which may be folded (or bent) or rolled, have been developed. The flexible display devices having diversely deformable shapes are easy to carry and may improve user's convenience.

### SUMMARY

The disclosure provides a display device with improved durability.

An embodiment of the invention provides a display device including: a display module which displays an image, where a folding area foldable with respect to a folding axis, a first non-folding area adjacent to a first side of the folding area, and a second non-folding area adjacent to a second side of the folding area are defined in the display module on a plane; and a cover panel coupled to a surface of the display module. In such an embodiment, the cover panel includes: a first support plate which supports the first non-folding area; a second support plate which supports the second non-folding area and is spaced apart from the first support plate; and an adhesive layer disposed between the display module and first and second support plates, where the adhesive layer couples the first and second support plates to the display module. In such an embodiment, the adhesive layer has a first surface in contact with the first and second support plates, the first surface has a pattern area in which an uneven pattern is defined, and the pattern area overlaps the folding area.

In an embodiment, when the display module is in an unfolded state, the folding area may be disposed between the first and second non-folding areas in a first direction, and the folding axis may extend in a second direction crossing the first direction, where the first and second support plates may be spaced apart from each other in the first direction.

In an embodiment, a portion of the first support plate may overlap a portion of the pattern area, and a portion of the second support plate may overlap another portion of the pattern area.

In an embodiment, the adhesive layer may include a first non-pattern area adjacent to a side of the pattern area and a second non-pattern area adjacent to an opposing side of the pattern area, where the first non-pattern area may correspond to the first non-folding area of the display module, and the second non-pattern area may correspond to the second non-folding area of the display module.

In an embodiment, an adhesive strength of the pattern area of the adhesive layer may be less than an adhesive strength of the first and second non-pattern areas.

In an embodiment, the adhesive layer may include a thermosetting resin or a photocurable resin.

In an embodiment, the pattern area of the adhesive layer may be formed by being cured through at least one of heat or light.

In an embodiment, the cover panel may further include a buffer film disposed between the display module and the adhesive layer.

In an embodiment, the cover panel may further include a buffer film adhesive layer which couples the display module to an upper surface of the buffer film, and a lower surface of the buffer film may be disposed on a second surface of the adhesive layer opposite to the first surface of the adhesive layer.

In an embodiment, the display module may include: a display panel which displays the image; and a window module disposed on an upper surface of the display panel.

In an embodiment, the display module may further include a functional layer disposed between the window module and the display panel.

In an embodiment, the display module may further include a protective film disposed on a lower surface of the display panel.

In an embodiment, the folding area of the display module may be in-folded in a way such that display surfaces, which display the image, face each other.

In an embodiment of the invention, a display device includes: a display module which displays an image, wherein a folding area foldable with respect to a folding axis, a first non-folding area adjacent to a side of the folding area, and a second non-folding area adjacent to an opposing side of the folding area are defined in the display module on a plane; and a cover panel coupled to a surface of the display module. In such an embodiment, the cover panel includes: a first support plate which supports the first non-folding area; a second support plate which supports the second non-folding area and is spaced apart from the first support plate; and an adhesive layer disposed between the display module and first and second support plates, where the adhesive layer couples the first and second support plates to the display module. In such an embodiment, the first and second support plates have surfaces in contact with the adhesive layer, and a first uneven pattern and a second uneven pattern are defined respectively on the surfaces of the first and second support plates, which are in contact with the adhesive layer, and the first and second uneven patterns overlap the folding area.

In an embodiment of the invention, a method for manufacturing a display device includes: preparing a display module which displays an image, where a folding area foldable with respect to a folding axis and first and second non-folding areas respectively adjacent to opposing sides of the folding area are defined in the display module on a plane; disposing an adhesive layer on a lower surface of the display module; forming an uneven pattern in a pattern area of the adhesive layer; curing the pattern area of the adhesive layer; and disposing first and second support plates, on a surface of the adhesive layer, to be spaced apart from each other. In such an embodiment, the pattern area of the adhesive layer overlaps the non-folding areas of the display module, and a portion of the first support plate overlaps a first section of the pattern area, and a portion of the second support plate overlaps a second section of the pattern area.

In an embodiment, when the display module is in an unfolded state, the folding area may be disposed between the first and second non-folding areas in a first direction, and the folding axis may extend in a second direction crossing the first direction, where the first and second support plates may be spaced apart from each other in the first direction.

In an embodiment, the adhesive layer may include a thermosetting resin or a photocurable resin.

In an embodiment, the adhesive layer may include a first non-pattern area adjacent to a side of the pattern area and a second non-pattern area adjacent to an opposing side of the pattern area. In such an embodiment, the curing the pattern area of the adhesive layer may include: preparing first and second masks below the surface of the adhesive layer; and irradiating the pattern area of the adhesive layer with light. The first mask may be disposed to overlap the first non-pattern area, and the second mask may be disposed to overlap the second non-pattern area.

In an embodiment, an adhesive strength of the pattern area after the curing of the pattern area may be less than an adhesive strength of the first and second non-pattern areas.

In an embodiment, the display module may include: a display panel which displays an image; and a protective film disposed on a lower surface of the display panel.

In an embodiment, the folding area of the display module may be in-folded in a way such that display surfaces, which display the image, face each other.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1 is a perspective view of a display device according to an embodiment of the invention;

FIG. 2A is a view illustrating the display device of FIG. 1 in a state in which the display device is in-folded along a first folding axis;

FIG. 2B is a view illustrating the display device of FIG. 1 a state in which the display device is out-folded along the first folding axis;

FIG. 3A is a view illustrating the display device of FIG. 1 a state in which the display device is in-folded along a second folding axis;

FIG. 3B is a view illustrating the display device of FIG. 1 a state in which the display device is out-folded along the second folding axis;

FIG. 4 is a perspective view of a display module according to an embodiment of the invention;

FIG. 5 is a plan view of the display module of FIG. 4;

FIG. 6 is a cross-sectional view taken along line I-I′ of FIG. 5;

FIG. 7 is an exploded perspective view of a display device according to an embodiment of the invention;

FIG. 8A is a cross-sectional view taken along line II-II′ of FIG. 7;

FIG. 8B is an enlarged view of a folding area of a cover panel of FIG. 8A;

FIG. 8C is a partial enlarged view illustrating the display device of FIG. 8A in a state in which the display is in-folded with respect to a first folding axis;

FIGS. 9A to 9E are views illustrating the bottom surfaces of various embodiments of a fourth adhesive layer;

FIGS. 10A to 10D are cross-sectional views illustrating a process for manufacturing a display device according to an embodiment of the invention;

FIG. 11A is a cross-sectional view of a display device according to an alternative embodiment of the invention;

FIG. 11B is an enlarged view of a folding area of a cover panel of FIG. 11A; and

FIG. 11C is a view illustrating the display device of FIG. 11A in a state in which the display device is in-folded with respect to a first folding axis.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Although the terms such as first and second are used to describe various components, these components should not be limited by these terms. The terms are only used to distinguish one component from other components. For example, a first component may be referred to as a second component, and similarly, a second component may be referred to as a first component without departing from the scope of the invention. The expression of a singular form includes plural forms unless definitely indicating a particular case in terms of the context.

When an element or layer is referred to as being “on” another element or layer, it can be directly on another element or layer, or intervening elements or layers may also be present. In contrast, when an element is referred to as being “directly on” another element, there are no intervening elements or layers present. The term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like reference numerals refer to like elements throughout.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The embodiments in this specification will be described with reference to plan views and cross-sectional views as ideal schematic views of the invention. Accordingly, shapes of the exemplary views may be modified according to manufacturing techniques and/or allowable errors. Therefore, the embodiments of the invention are not limited to the predetermined shape illustrated in the exemplary views, but may include other shapes that are created according to manufacturing processes. Thus, areas exemplified in the drawings have general properties, and shapes of the exemplified areas are used to illustrate a predetermined shape of a device region. Thus, this should not be construed as limited to the scope of the invention.

Hereinafter, embodiments of the invention will be described with reference to the accompanying drawings.

FIG. 1 is a perspective view of a display device according to an embodiment of the invention.

Referring to FIG. 1, an embodiment of a display device DD has a short side in a first direction DR1 and a long side in a second direction DR2 crossing the first direction DR1. However, the shape of the display device DD is not limited thereto, and the display device DD may be modified to have one of various shapes.

The display device DD may be a folding-type (foldable) electronic device. In an embodiment, the display device DD may be folded with respect to folding axes FX1 and FX2 extending in predetermined directions. Hereinafter, a state in which the display device is folded with respect to the folding axes FX1 and FX2 is defined as a folding state, and a state in which the display device is unfolded is defined as a non-folding state.

The folding axis FX1 or FX2 may extend in the first direction DR1 or the second direction DR2. In an embodiment of the invention, a folding axis extending in the second direction DR2 is defined as the first folding axis FX1, and a folding axis extending in the first direction DR1 is defined as the second folding axis FX2. The display device DD may include a single folding axis selected from the first folding axis FX1 and the second folding axis FX2. That is, the display device DD may be folded with respect to one of the first folding axis FX1 and the second folding axis FX2. Herein, a folding axis may be an imaginary axis with which the display device is folded or unfolded.

In an embodiment, the display device DD may be small-to-medium scale electronic devices, such as mobile phones, tablets, vehicular navigation devices, or game consoles, as well as large scale electronic devices, such as televisions, or monitors. These are merely exemplary, and thus may be employed in other electronic devices as long as not departing from the invention.

In an embodiment, as illustrated in FIG. 1, the display device DD may display, in a third direction DR3, an image IM on a display surface IS which is parallel to each of the first direction DR1 and the second direction DR2. The display surface IS on which the image IM is displayed may correspond to a front surface of the display device DD.

The display surface IS of the display device DD may be divided into a plurality of regions. A display area DA and a non-display area NDA may be defined on the display surface IS of the display device DD.

The display area DA may be a region on which the image IM is displayed, and the image IM is viewed through the display area DA by a user. The display area DA may have a tetragonal shape. The non-display area NDA may surround the display area DA. Accordingly, the shape of the display area DA may be defined substantially by the non-display area NDA. However, this is merely exemplary, and alternatively, the non-display area NDA may be disposed adjacent to only one side of the display area DA, or omitted. In an embodiment, the display device DD may be various modified and is not limited to one embodiment.

The non-display area NDA is a region adjacent to the display area DA, and the image IM is not displayed thereon. A bezel area of the display device DD may be defined by the non-display area NDA.

The non-display area NDA may surround the display area DA. However, this is merely exemplary. Alternatively, the non-display area NDA may be defined to be adjacent to only a portion of an edge of the display area DA, and is not limited to one embodiment.

In an embodiment, the display device DD may sense a user's input thereon. In one embodiment, for example, the input of a user includes various types of external inputs such as a touch by a portion of the user's body, light, heat, or pressure. In an embodiment, the input of a user may include an input generated by using a mechanism such as a touch pen or a stylus pen. In an embodiment, the display device DD may also sense the user's input applied to a side surface or a bottom surface of the display device DD depending on a structure of the display device DD, and is not limited to one embodiment.

FIG. 2A is a view illustrating the display device of FIG. 1 in a state in which the display device is in-folded along the first folding axis FX1, and FIG. 2B is a view illustrating the display device of FIG. 1 in a state in which the display device is out-folded along the first folding axis FX1.

Referring to FIGS. 1 and 2A, an embodiment of the display device DD may be in-folded with respect to the first folding axis FX1.

In such an embodiment of the display device DD, a plurality of regions may be defined according to the types of operations. The plurality of the regions may be divided into a folding area FA and one or more non-folding areas NFA1 and NFA2. The folding area FA may be defined between two non-folding areas NFA1 and NFA2.

In an embodiment of the invention, the non-folding areas NFA1 and NFA2 may include a first non-folding area NFA1 and a second non-folding area NFA2, for example. The first non-folding area NFA1 is adjacent to a side of the folding area FA in the first direction DR1, and the second non-folding area NFA2 is adjacent to an opposing side of the folding area FA in the first direction DR1.

The display device DD may be out-folded or in-folded. Here, the in-folding indicates that the display device DD is folded so that regions of the display surface IS face each other, and the out-folding indicates that the display device DD is folded so that regions of the rear surface thereof face each other.

The folding area FA is a region which is folded on the basis of the first folding axis FX1 and substantially forms curvature. Here, the first folding axis FX1 may extend in the second direction DR2, that is, in a direction (a long side direction) parallel to the long side of the display device DD.

The display device DD of FIG. 2A may be in-folded so that the display surface IS of the first non-folding area NFA1 and the display surface IS of the second non-folding area NFA2 face each other.

Referring to FIG. 2B, the display device DD may be out-folded with respect to the first folding axis FX1. When the display device DD is out-folded, the display surface IS may be exposed to the outside.

In an embodiment, the display device DD may be both in-folded and out-folded. For convenience of description, embodiments where the display device DD is either in-folded or out-folded will hereinafter be described in detail.

FIG. 3A is a view illustrating the display device of FIG. 1 in a state in which the display device is in-folded along the second folding axis FX2, and FIG. 3B is a view illustrating the display device of FIG. 1 in a state in which the display device is out-folded along the second folding axis FX2.

Referring to FIGS. 3A and 3B, an embodiment of the display device

DD may be in-folded or out-folded with respect to the second folding axis FX2. The second folding axis FX2 may extend in the first direction DR1, and this direction may be a direction (a short direction) parallel to the short side of the display device DD.

In an embodiment, a single folding area FA is defined in the display device DD, but the embodiment of the invention is not limited thereto. According to an alternative embodiment of the invention, a plurality of folding areas may be defined in the display device DD.

FIG. 4 is a perspective view of a display module according to an embodiment of the invention.

Referring to FIG. 4, an embodiment of a display module DM according to the invention may include a display panel DP for displaying an image and a window module WM disposed on the display panel DP. The display module DM constitutes a portion of the display device DD (illustrated in FIG. 1), and particularly, the display module DM may provide the display surface IS (see FIG. 1) of the display device DD.

The display panel DP may be a flexible display panel. Accordingly, the display panel DP may be folded or unfolded with respect to a first folding axis FX1. In an embodiment of the invention, the display panel DP may be an organic light emitting display panel, for example.

The display panel DP may be divided into a folding area FA, a first non-folding area NFA1, and a second non-folding area NFA2. In an embodiment, the display panel DP may be divided into a non-bending area NBA and a bending area BA. The folding area FA, the first non-folding area NFA1, and a portion of the second non-folding area NFA2 of the display panel DP may be included in the non-bending area NBA, and the remaining portions of the second non-folding area NFA2 may be included in the bending area BA. The bending area BA will be described later in greater detail.

The upper surface of the window module WM defines the display surface IS of the display device DD of FIG. 1. The window module WM may be optically transparent. Accordingly, an image generated in the display panel DP passes through the window module WM, and thus may be easily recognized by a user.

The window module WM may include or be made of a flexible material. Accordingly, the window module WM may be folded or unfolded with respect to the first folding axis FX1. In such an embodiment, when the shape of the display panel DP is deformed, the shape of the window module WM may be deformed together therewith.

The window module WM reduces or absorbs external impact as well as allows the image from the display panel DP to pass therethrough, and thus prevents the display panel DP from being damaged or malfunctioning due to external impact. The external impact may be a force from the outside expressed as a pressure, a stress, or the like, and indicate a force that causes defects of the display panel DP. The window module WM may prevent a failure of the display panel DP by reducing bending deformation, and compressive deformation and/or tensile deformation of the display panel DP due to a point impact or a surface impact.

A functional layer FC may be disposed between the display panel DP and the window module WM. In an embodiment of the invention, the functional layer FC may include a reflection prevention layer for blocking the reflection of the external light. The reflection prevention layer may prevent elements constituting the display device DD from being visible from the outside due to the external light that is incident through the front surface of the display device DD. The reflection prevention layer may include a polarization film and/or a phase delay film. The number of the phase delay films and the phase delay length (λ/4 or λ/2) of the phase delay film may be determined according to the operation principle of the reflection prevention layer.

The functional layer FC may further include an input sensing layer for sensing an input TC (see FIG. 1) of a user. In an embodiment, the input sensing layer may be formed as a layer separated from the display panel DP and coupled thereto through an adhesive layer. Alternatively, an input sensing unit may be integrated with the display panel DP through a continuous process. In such an embodiment, the input sensing unit may be disposed directly on a thin film encapsulation layer (not shown) of the display panel DP. Here, “being disposed directly on” means that the input sensing unit is disposed on the display panel DP without an additional adhesive member. In an embodiment, the input sensing unit is disposed on the upper surface of the display panel DP, but is not limited thereto. In an alternative embodiment, the input sensing unit may be disposed on the lower surface of the display panel.

The window module WM and the functional layer FC may be adhered to each other through a first adhesive layer AL1. The display panel DP and the functional layer FC may be adhered to each other through a second adhesive layer AL2.

Each of the first adhesive layer AL1 and the second adhesive layer AL2 may be optically transparent. Each of the first adhesive layer AL1 and the second adhesive layer AL2 is an adhesive layer manufactured by applying and curing a liquid-phase adhesive material, or an adhesive sheet manufactured separately. In an embodiment, for example, each of the first adhesive layer AL1 and the second adhesive layer AL2 may be a pressure sensitive adhesive (“PSA”), an optical clear adhesive (“OCA”), or an optical clear resin (“OCR”).

A protective film PF may be disposed on the rear surface of the display panel DP. The protective film PF may include a polymeric material. The protective film PF may be a layer for absorbing impact applied from the outside and protecting the display panel DP against the impact. The protective film PF may be adhered to the rear surface of the display panel DP through a third adhesive layer AL3.

FIG. 4 illustrates an embodiment in which the protective film PF is disposed only on the rear surface of the display panel DP, but the embodiment of the invention is not limited thereto. In one alternative embodiment, for example, the display module DM may further include an upper protective film disposed between the display panel DP and the functional layer FC.

A material constituting the protective film PF is not limited to a plastic or a resin, and may include an organic/inorganic composite material. The protective film PF may include a porous organic layer and inorganic substances filled into the porosities of the organic layer.

FIG. 5 is a plan view of the display module of FIG. 4. Herein, “a plan view” may mean a plan view in the third direction DR3.

The display module DM of FIG. 5 may be in a state in which the window module WM, the functional layer FC, the display panel DP, and the protective film PF are coupled all together.

In an embodiment, the display module DM may further include a flexible circuit board FCB connected to the display panel DP and a driving chip DIC mounted on the flexible circuit board FCB. The flexible circuit board FCB may be connected to a main circuit board MCB. In such an embodiment, components such as a control chip and a plurality of passive elements active elements may be mounted on the main circuit board MCB. The main circuit board MCB may include or be made of a flexible film like the flexible circuit board FCB.

In an embodiment, the display module DM includes a chip on film (“COF”) structure in which the driving chip DIC is mounted on the flexible circuit board FCB. However, the embodiment of the invention is not limited thereto. In one alternative embodiment, for example, the display module DM may include a chip on panel (“COP”) structure or a chip on glass (“COG”) structure in which the driving chip DIC is mounted on the display panel DP.

FIG. 6 is a cross-sectional view taken along line I-I′ of FIG. 5.

Referring to FIGS. 5 and 6, an embodiment of the display module DM may include the flexible display panel DP. In FIG. 6, the display panel DP is schematically illustrated as a single layer for convenience of illustration. Although not shown in the drawing, the display panel DP may include a base layer, a circuit layer, a light emitting element layer, and an encapsulation layer.

In an embodiment, the display panel DP may be divided into the bending area BA and the non-bending area NBA. The non-bending area NBA may be a region including a display area DA and a non-display area NDA of the display panel DP. The folding area FA, the first non-folding area NFA1, and the portion of the second non-folding area NFA2 of the display panel DP may be included in the non-bending area NBA, and the remaining portions of the second non-folding area NFA2 may be included in the bending area BA. The bending area BA of the display panel DP may be bent at a predetermined curvature toward the rear surface of the display panel DP.

The bending area BA may include a curvature area CA and a facing area FAA. The curvature area CA is adjacent to the non-bending area NBA and is a substantially bent region. The facing area FAA is adjacent to the curvature area CA and faces the non-bending area NBA in a bent state. The flexible circuit board FCB is connected to the facing area FAA of the display panel DP.

The protective film PF is disposed corresponding to both the non-bending area NBA and the facing area FAA, and may be not disposed in the curvature area CA. The bending open portion OPP may be defined in the protective film PF to correspond to the curvature area CA. In such an embodiment, the protective film PF is removed from the curvature area CA, such that the occurrence of stress in the curvature area CA when bent may be reduced. In such an embodiment, where the bending open portion OPP is defined in the protective film PF, a portion of the third adhesive layer AL3 corresponding to the bending open portion OPP may be removed.

In an alternative embodiment of the invention, a protective film PF may have a groove portion which is defined to correspond to the curvature area CA. The protective film PF may be formed to be thinner than other areas NBA and FAA.

FIG. 7 is an exploded perspective view of a display device according to an embodiment of the invention, and FIG. 8A is a cross-sectional view taken along line II-II′ of FIG. 7.

Referring to FIGS. 7 and 8A, a display device DD includes a display module DM and a cover panel CVP. The display module DM may include the window module WM, the functional layer FC, the display panel DP, and the protective film PF, as illustrated in FIG. 4. In such an embodiment, the display module DM may have the same structure as the display module DM described above with reference to FIGS. 4 and 5, and any repetitive detailed description of the display module DM will be omitted.

The cover panel CVP is disposed below the display module DM. The cover panel CVP may be coupled to the bottom surface of the display module DM. The cover panel CVP may support the bottom surface of the display module DM.

The cover panel CVP may have a structure in which a plurality of layers are laminated one on another in a third direction DR3.

In an embodiment of the invention, the cover panel CVP may include a support plate SP and a fourth adhesive layer AL4. The support plate SP is disposed on the bottom surface of the display module DM. The support plate SP may be a metal plate. In one embodiment, for example, the support plate SP may be a stainless-steel plate. The strength of the support plate SP may be greater than the strength of the display module DM.

The support plate SP may include a first plate SP1 for supporting a first non-folding area NFA1 of the display module DM and a second plate SP2 for supporting a second non-folding area NFA2 of the display module DM. Each of the first and second support plates SP1 and SP2 may have a plate shape.

The first support plate SP1 and the second support plate SP2 may be spaced apart from each other in a first direction DR1. The first support plate SP1 and the second support plate SP2 may be spaced apart from each other, corresponding to the folding area FA. The first support plate SP1 may overlap a portion of the folding area FA, and the second support plate SP2 may overlap a portion of the folding area FA. In such an embodiment, the spaced distance in the first direction DR1 between the first support plate SP1 and the second support plate SP2 may be less than the width of the folding area FA.

The fourth adhesive layer AL4 is disposed between the support plate SP and the display module DM. The fourth adhesive layer AL4 may be disposed corresponding to the entire bottom surface of the display module DM.

The cover panel CVP further includes a buffer film BF and a fifth adhesive layer AL5. The buffer film BF is provided between the fourth adhesive layer AL4 and the display module DM. The buffer film BF may include a polymeric material. The buffer film BF may be a layer for absorbing impact applied from the outside. The buffer film BF may include at least one material selected from polyurethane, plastic polyurethane, and urethane rubber. The buffer film BF may be adhered to the bottom surface of the display module DM through the fifth adhesive layer AL5. In an alternative embodiment, the fifth adhesive layer AL5 and the buffer film BF may be omitted.

FIGS. 7 and 8A illustrate an embodiment having a structure of the buffer film BF composed of a single layer, but the embodiment of the invention is not limited thereto. Alternatively, the buffer film BF may include a plurality of layers, and the position thereof is not limited to the position described above.

The support plate SP may be fixed to the buffer film BF by the fourth adhesive layer AL4. The support plate SP may be attached to the bottom surface of the buffer film BF by the fourth adhesive layer AL4. The fourth adhesive layer AL4 and the buffer film BF may be formed entirely on the folding area FA and the first and second non-folding areas NFA1 and NFA2.

The fifth adhesive layer AL5 is disposed between the buffer film BF and the display module DM, and thus the buffer film BF is attached to the bottom surface of the display module DM.

Each of the fourth and fifth adhesive layers AL4 and AL5 may be optically transparent. Each of the fourth and fifth adhesive layers AL4 and AL5 is an adhesive layer manufactured by applying and curing a liquid-phase adhesive material, or an adhesive sheet manufactured separately. In one embodiment, for example, each of the fourth and fifth adhesive layers AL4 and AL5 may be a PSA, an OCA, or an OCR.

FIGS. 7 and 8A illustrate an embodiment in which the support plate SP is defined by the two support plates SP1 and SP2 spaced apart from each other, but the embodiment of the invention is not limited thereto. In an alternative embodiment, where the number of the folding axes FX1 increases, the support plate SP may be provided with a plurality of support plates which are separated with respect to the folding axes FX1. The first and second support plates SP1 and SP2 may be disposed corresponding to the non-folding areas, respectively.

When a curvature area CA of the display module DM is bent, a facing area FAA faces a non-bending area NBA, and a circuit board FCB and a main circuit board MCB connected to the facing area FAA are disposed aligned with the non-bending area NBA of the display panel DP. The first and second support plates SP1 and SP2 may be disposed overlapping the non-bending area NBA. Also, after display module DM is bent, the circuit board FCB and the main circuit board MCB may be disposed on the bottom surface of the second support plate SP2.

In an embodiment, although not shown, the display device DD may further include an adhesive layer for attaching the circuit board FCB and the main circuit board MCB to the second support plate SP2. Thus, in such an embodiment, the circuit board FCB and the main circuit board MCB may be fixed to the bottom surface of the second support plate SP2.

In an embodiment, although not shown, the display device DD may further include a rear case disposed below the support plate SP, and components for operating the display device DD, such as a battery and a main PCB, may be mounted in a space between the support plate SP and the rear case.

FIG. 8B is an enlarged view of the folding area FA of the cover panel CVP of FIG. 8A. FIG. 8C is a partial enlarged view illustrating the display device DD of FIG. 8A in a state in which the display device DD is in-folded with respect to the first folding axis FX1.

Referring to FIGS. 8B and 8C, the bottom surface of the fourth adhesive layer AL4 includes an uneven pattern UEP in the folding area FA. The uneven pattern UEP includes a first uneven pattern UEP1, a second uneven pattern UEP2, and a third uneven pattern UEP3. The first uneven pattern UEP1, the second uneven pattern UEP2, and the third uneven pattern UEP3 have a same shape as each other, but the embodiment of the invention is not limited thereto. In one alternative embodiment, for example, the first uneven pattern UEP1 and the second uneven pattern UEP2 have a same shape as each other, but the third uneven pattern UEP3 may have a different shape from the first uneven pattern UEP1 and the second uneven pattern UEP2. In another alternative embodiment, the first uneven pattern UEP1, the second uneven pattern UEP2, and the third uneven pattern UEP3 have shapes different from each other.

The first uneven pattern UEP1 of the fourth adhesive layer AL4 overlaps the first support plate SP1. The first uneven pattern UEP1 of the fourth adhesive layer AL4 may have a sawtooth-like shape, which is formed in the third direction DR3, to minimize the adhesion surface area with the first support plate SP1.

The second uneven pattern UEP2 of the fourth adhesive layer AL4 overlaps the second support plate SP2. The second uneven pattern UEP2 of the fourth adhesive layer AL4 may have a sawtooth-like shape, which is formed in the third direction DR3, to minimize the adhesion surface area with the second support plate SP2.

In a state in which the display device DD is unfolded, the first uneven pattern UEP1 and the second uneven pattern UEP2 of the fourth adhesive layer AL4 are in contact with the first support SP1 and the second support plate SP2, respectively, as shown in FIG. 8B.

In a state in which the display device DD is in-folded with respect to the first folding axis FX1 as illustrated in FIG. 8C, the first uneven pattern UEP1 and the second uneven pattern UEP2 of the fourth adhesive layer AL4 are spaced apart from the first support SP1 and the second support plate SP2, as shown in FIG. 8C.

In an embodiment, the fourth adhesive layer AL4 include or is made of a material having an adhesive force to fix the first support plate SP1 and the second support plate SP2 to the buffer film BF. In the folding area FA, the folding area of the fourth adhesive layer AL4 may be thermally cured or photo-cured to reduce the adhesive force of the fourth adhesive layer AL4. However, the adhesive force of the fourth adhesive layer AL4 may be maintained at a certain degree, even after the curing process is performed. In an embodiment of the invention, the bottom surface of the fourth adhesive layer AL4 includes the uneven pattern UEP in the folding area FA. The uneven pattern UEP of the fourth adhesive layer AL4 may minimize the contact surface area between the fourth adhesive layer AL4 and the first and second support plates SP1 and SP2 in the folding area FA. Thus, when the display device DD is in-folded with respect to the first folding axis FX1, the first support plate SP1 and the second support plate SP2 may be easily separated from the fourth adhesive layer AL4 in the folding area FA.

In an embodiment, undesired particles may be introduced between the first support plate SP1 and the second support plate SP2 during a production process. Since the fourth adhesive layer AL4 has the adhesive force, the introduced particles may be attached to the fourth adhesive layer AL4. According to an embodiment of the invention, since the fourth adhesive layer AL4 includes the uneven pattern UEP, the adhesion surface area with the particles is minimized, and thus the adhesive strength between the particles and the fourth adhesive layer AL4 is not strong. Thus, the particles may be effectively separated from the fourth adhesive layer AL4 by an air flow or an air gap between the particles and the uneven pattern UEP of the fourth adhesive layer AL4.

FIGS. 9A to 9E are views illustrating the bottom surfaces of various embodiments of a fourth adhesive layer AL4.

The bottom surfaces of embodiments of the fourth adhesive layer AL4 illustrated in FIGS. 9A to 9E have different uneven patterns UEPa to UEPe in a pattern area PA. The uneven patterns UEPa to UEPe may be patterns that may minimize the adhesion surface area with a first support plate SP1 and a second support plate SP2.

Referring to FIG. 9E, in an embodiment, the uneven pattern UEPe may include a first uneven pattern UEPe1, a second uneven pattern UEPe2, and a third uneven pattern UEPe3. The first uneven pattern UEPe1 may overlap the first support plate SP1 of FIG. 7, and the third uneven pattern UEPe3 may overlap the second support plate SP2 of FIG. 7.

The first uneven pattern UEPe1 and the third uneven pattern UEPe3 have a same shape as each other, and may have a shape for minimizing the adhesion surface area with the first support plate SP1 and the second support plate SP2. The second uneven pattern UEPe2 may have a different shape from the first uneven pattern UEPe1 and the third uneven pattern UEPe3.

In an embodiment, as illustrated in FIGS. 9A to 9E, the shapes of the uneven patterns UEPa to UEPe formed in the pattern area PA of the fourth adhesive layer AL4 may be variously modified. In such an embodiment, a shape of the uneven pattern formed in the pattern area PA of the fourth adhesive layer AL4 is not limited to those illustrated in FIGS. 9A to 9E. The pattern area PA of the fourth adhesive layer AL4 overlaps the folding area FA of the display module DM illustrated in FIG. 8A, and may have the substantially same surface area as the folding area FA.

FIGS. 10A to 10D are cross-sectional views illustrating a process for manufacturing a display device according to an embodiment of the invention.

Referring to FIG. 10A, in an embodiment of a method of manufacturing a display device, a display module DM is provided, which displays an image and in which a folding area FA foldable with respect to a virtual first folding axis FX1 and first and second non-folding areas NFA1 and NFA2 respectively adjacent to both sides of the folding area FA are defined on a plane.

Although not shown, a protective film may be attached to the upper surface of the display module DM. The protective film may be for preventing the upper surface of the display module DM from being damaged during a manufacturing process and facilitating handling during the manufacturing process. Since such a protective film is removed in the manufacturing process, it is preferable that the adhesive force between the protective film and the display module DM is not strong. Although not shown, the protective film may include an adhesive layer and a protective film base.

In an embodiment, a protective component PP may be provided, In such an embodiment, the protective component PP may include a first liner LNR1, a second liner LNR2, a fourth adhesive layer AL4, a fifth adhesive layer AL5, and a buffer film BF.

The fourth adhesive layer AL4 may be disposed on the lower surface of the buffer film BF, and the fifth adhesive layer AL5 may be disposed on the upper surface of the buffer film BF. The fourth adhesive layer AL4 may include a thermosetting resin or a photocurable resin.

The first liner LNR1 and the second liner LNR2 may be carrier films for preventing the fifth adhesive layer AL5 and the fourth adhesive layer AL4 from being damaged, respectively, in a manufacturing process and facilitating handling during the manufacturing process. Since the first liner LNR1 and the second liner LNR2 are removed in the manufacturing process, it is desired that the adhesive forces between the first and second liners LNR1 and LNR2 and the fifth and fourth liners AL5 and AL4 are not strong, respectively.

In such an embodiment, the first liner LNR1 of the protective component PP is removed, and the protective component PP is attached directly on the lower surface of the display module DM by using the fifth adhesive layer AL5 of the protective component PP.

In an embodiment, the display module DM may be in a state in which the window module WM, the functional layer FC, the display panel DP, and the protective film PF are coupled to one another as illustrated in FIG. 6. In an alternative embodiment, the display module DM may include only the display panel DP. In such an embodiment, the protective component PP may be attached to the bottom surface of the display panel DP by using the fifth adhesive layer AL5 of the protective component PP.

In an embodiment, after the protective component PP is attached to the display module DM, the second liner LNR2 may be removed. In an alternative embodiment, the protective component PP may not include the first liner LNR1 and the second liner LNR2. In another alternative embodiment, the protective component PP may not include the buffer film BF, and may include only the first liner LNR1, the second liner LNR2, and the fourth adhesive layer AL4. In such an embodiment, the first liner LNR1 and the second liner LNR2 may be disposed on the upper surface and the lower surface of the fourth adhesive layer AL4, respectively. In such an embodiment, the fourth adhesive layer AL4 may be attached directly to the lower surface of the display module DM.

Referring to FIG. 10B, a pattern generating device JG is disposed below the fourth adhesive layer AL4. The pattern generating device JG may include an unevenness forming pattern UEP_J on the upper surface thereof.

An uneven pattern may be formed, by using the pattern generating device JG, in a pattern area PA of the fourth adhesive layer AL4 corresponding to the folding area FA of the display module DM. The fourth adhesive layer AL4 may include a material having modulus that allows deformation due to an external force. Thus, a temporary uneven pattern WRK may be formed on the lower surface (a first surface) of the pattern area PA of the fourth adhesive layer AL4 by pressing the unevenness forming pattern UEP_J of the pattern generating device JG thereto.

Referring to FIG. 10C, the temporary uneven pattern WRK may be formed on the lower surface of the pattern area PA of the fourth adhesive layer AL4. Since the fourth adhesive layer AL4 has the modulus that allows deformation due to an external force, the temporary uneven pattern WRK may be in a deformable state.

The fourth adhesive layer AL4 includes a first non-pattern area NPA1 adjacent to a side of the pattern area PA and a second non-pattern area NPA2 adjacent to an opposing side of the pattern area PA.

In an embodiment, a first mask MSK1 may be disposed below the first non-pattern area NPA1, and a second mask MSK2 may be disposed below the second non-pattern area NPA2. The first mask MSK1 and the second mask MSK2 may include or be composed of a material through which ultraviolet (“UV”) light is not transmitted, or a UV blocking material.

In such an embodiment, as shown in FIG. 10C, a light generation device LD is disposed below the pattern area PA of the fourth adhesive layer AL4. The light generation device LD may be a device that generates a UV light.

The pattern area PA of the fourth adhesive layer AL4 may be cured by the UV light which is output from the light generation device LD. In one embodiment, for example the fourth adhesive layer AL4 may be cured by heat.

The light generation device LD may cure the pattern area PA while covering the entire pattern area PA of the fourth adhesive layer AL4 at a fixed location. In an alternative embodiment, the light generation device LD may cure the pattern area PA of the fourth adhesive layer AL4 by generating the UV light while moving in a predetermined direction. The cured degree of the pattern area PA of the fourth adhesive layer AL4 may be controlled by adjusting conditions such as the intensity, wavelength, and temperature of the UV light, which is output from the light generation device LD, and the time of UV light irradiation.

Referring to FIGS. 10C and 10D, an uneven pattern UEP may be formed after the pattern area PA of the fourth adhesive layer AL4 is cured by the light generation device LD. A support plate SP including a first support plate SP1 and a second support plate SP2 is disposed on the lower surface of the fourth adhesive layer AL4 after the first mask MSK1 and the second mask MSK2 are removed. The first support plate SP1 and the second support plate SP2 are coupled to the buffer film BF by the fourth adhesive layer AL4.

The first support plate SP1 may support the first non-folding area NFA1 of the display module DM, and the second support plate SP2 may support the second non-folding area NFA2 of the display module DM.

The first support plate SP1 and the second support plate SP2 may be spaced apart from each other in a first direction DR1. The first support plate SP1 and the second support plate SP2 may be spaced apart from each other, corresponding to the folding area FA. The first support plate SP1 may overlap a portion of the folding area FA, and the second support plate SP2 may overlap a portion of the folding area FA. In such an embodiment, the spaced distance in the first direction DR1 between the first support plate SP1 and the second support plate SP2 may be less than the width of the folding area FA.

The uneven pattern UEP of the fourth adhesive layer AL4 includes a first uneven pattern UEP1, a second uneven pattern UEP2, and a third uneven pattern UEP3. The first uneven pattern UEP1 (or a first section of the uneven pattern UEP) may be in contact with a portion of the first support plate SP1, and the second uneven pattern UEP2 (or a second section of the uneven pattern UEP) may be in contact with a portion of the second support plate SP2. The adhesion surface area between the fourth adhesive layer AL4 and the first and second support plates SP1 and SP2 may be substantially reduced or minimized by the first uneven pattern UEP1 and the second uneven pattern UEP2. The first uneven pattern UEP1, the second uneven pattern UEP2, and the third uneven pattern UEP3 may have a same shape as or different shapes from each other. The shapes of the first uneven pattern UEP1, the second uneven pattern UEP2, and the third uneven_J of the pattern generating device JG of FIG. 10B.

The first support plate SP1 and the second support plate SP2 are coupled to the fourth adhesive layer AL4, and thus a cover panel CVP may be defined. The cover panel CVP may be coupled to the bottom surface of the display module DM and support the bottom surface of the display module DM.

FIG. 11A is a cross-sectional view of a display device DD2 according to an alternative embodiment of the invention. FIG. 11B is an enlarged view of a folding area FA of a cover panel CVP2 of FIG. 11A. FIG. 11C is a view illustrating, as an example, a state in which the display device DD2 of FIG. 11A is in-folded with respect to a first folding axis FX1.

In the display device DD2 of FIGS. 11A to 11C, the similar components as those in the display device DD of FIGS. 8A to 8C are designated by the same reference symbols, and any repetitive detailed descriptions thereof will be omitted.

Referring to FIG. 11A, FIG. 11B, and FIG. 11C, in an embodiment of the display device DD2, the cover panel CVP2 may include a support plate SP and a fourth adhesive layer AL4. The support plate SP is disposed on the bottom surface of a display module DM. The support plate SP may be a metal plate. In one embodiment, for example, the support plate SP may be a stainless-steel plate. The strength of the support plate SP may be greater than the strength of the display module DM.

The cover panel CVP2 further includes a buffer film BF and a fifth adhesive layer AL5.

The fourth adhesive layer AL4 is disposed between the support plate

SP and the display module DM. The fourth adhesive layer AL4 may be disposed corresponding to the entire bottom surface of the display module DM. The support plate SP may be fixed to the buffer film BF by the fourth adhesive layer AL4. The support plate SP may be attached to the bottom surface of the buffer film BF by the fourth adhesive layer AL4. The fourth adhesive layer AL4 and the buffer film BF may be formed entirely on a folding area FA and first and second non-folding areas NFA1 and NFA2.

The support plate SP include a first support plate SP1 and a second support plate SP2.

The upper surfaces of the first support plate SP1 and the second support plate SP2 include a first uneven pattern UE1 and a second uneven pattern UE2, respectively, in the folding area FA. The first uneven pattern UE1 and the second uneven pattern UE2 have a same shape as each other, but the embodiment of the invention is not limited thereto. In an alternative embodiment, the first uneven pattern UE1 and the second uneven pattern UE2 may have shapes different from each other.

The first uneven pattern UE1 of the first support plate SP1 overlaps the fourth adhesive layer AL4. The second uneven pattern UE2 of the second support plate SP2 overlaps the fourth adhesive layer AL4. The first uneven pattern UE1 and the second uneven pattern UE2 may have a sawtooth-like shape, which is formed in a third direction DR3, so as to minimize the adhesion surface area with the fourth adhesive layer AL4. The first uneven pattern UE1 and the second uneven pattern UE2 are not limited to the sawtooth-like shape, and may be variously modified to have another shape in which the adhesion surface area with the fourth adhesive layer AL4 is reduced or minimized.

In a state in which the display device DD2 is unfolded, the first uneven pattern UE1 of the first support plate SP1 and the second uneven pattern UE2 of the second support plate SP2 are in contact with the fourth adhesive layer AL4, as shown in FIG. 11B.

In a state in which the display device DD2 is in-folded with respect to the first folding axis FX1, the first uneven pattern UE1 of the first support plate SP1 and the second uneven pattern UE2 of the second support plate SP2 are spaced apart from the fourth adhesive layer AL4,a shown in FIG. 11C.

The adhesion surface area between the fourth adhesive layer AL4 and the first and second support plates SP1 and SP2 may be minimized in the folding area FA by the first uneven pattern UE1 of the first support plate SP1 and the second uneven pattern UE2 of the second support plate SP2. Thus, when the display device DD2 is in-folded with respect to the first folding axis FX1, the first support plate SP1 and the second support plate SP2 may be easily separated from the fourth adhesive layer AL4 in the folding area FA.

According to embodiments of the invention, the durability and display quality of the display panel may be improved.

The invention should not be construed as being limited to the exemplary embodiments set forth herein. Rather, these exemplary embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device comprising:
a display module which displays an image, wherein a folding area foldable with respect to a folding axis, a first non-folding area adjacent to a first side of the folding area, and a second non-folding area adjacent to a second side of the folding area are defined in a display module on a plane; and
a cover panel coupled to a surface of the display module,
wherein the cover panel comprises:
a first support plate which supports the first non-folding area;
a second support plate which supports the second non-folding area and is spaced apart from the first support plate; and
an adhesive layer disposed between the display module and first and second support plates, wherein the adhesive layer couples the first and second support plates to the display module,
wherein the adhesive layer has a first surface in contact with the first and second support plates, the first surface has a pattern area in which an uneven pattern is defined, and the pattern area overlaps the folding area.

2. The display device of claim 1, wherein when the display module is in an unfolded state, the folding area is disposed between the first and second non-folding areas in a first direction, and the folding axis extends in a second direction crossing the first direction,
wherein the first and second support plates are spaced apart from each other in the first direction.

3. The display device of claim 2, wherein
a portion of the first support plate overlaps a portion of the pattern area, and
a portion of the second support plate overlaps another portion of the pattern area.

4. The display device of claim 1, wherein
the adhesive layer comprises a first non-pattern area adjacent to a side of the pattern area and a second non-pattern area adjacent to an opposing side of the pattern area,
wherein the first non-pattern area corresponds to the first non-folding area of the display module, and the second non-pattern area corresponds to the second non-folding area of the display module.

5. The display device of claim 4, wherein an adhesive strength of the pattern area of the adhesive layer is less than an adhesive strength of the first and second non-pattern areas.

6. The display device of claim 1, wherein the adhesive layer comprises a thermosetting resin or a photocurable resin.

7. The display device of claim 6, wherein the pattern area of the adhesive layer is formed by being cured through at least one selected from a heat and a light.

8. The display device of claim 1, wherein the cover panel further comprises a buffer film disposed between the display module and the adhesive layer.

9. The display device of claim 8, wherein the cover panel further comprises
a buffer film adhesive layer which couples the display module to an upper surface of the buffer film, and
a lower surface of the buffer film is disposed on a second surface of the adhesive layer opposite to the first surface of the adhesive layer.

10. The display device of claim 1, wherein the display module comprises:
a display panel which displays the image; and
a window module disposed on an upper surface of the display panel.

11. The display device of claim 10, wherein the display module further comprises:
a protective film disposed on a lower surface of the display panel.

12. The display device of claim 1, wherein the folding area of the display module is in-folded in a way such that display surfaces, which displays the image, face each other.

13. A display device comprising:
a display module which displays an image, wherein a folding area foldable with respect to a folding axis, a first non-folding area adjacent to a side of the folding area, and a second non-folding area adjacent to an opposing side of the folding area are defined in the display module on a plane; and
a cover panel coupled to a surface of the display module,
wherein the cover panel comprises:
a first support plate which supports the first non-folding area;
a second support plate which supports the second non-folding area and is spaced apart from the first support plate; and
an adhesive layer disposed between the display module and first and second support plates, wherein the adhesive layer couples the first and second support plates to the display module,
wherein the first and second support plates have surfaces in contact with the adhesive layer, and a first uneven pattern and a second uneven pattern are defined respectively on the surfaces of the first and second support plates, which are in contact with the adhesive layer, and
wherein the first and second uneven patterns overlap the folding area.

14. The display device of claim 13, wherein
when the display module is in an unfolded state, the folding area is disposed between the first and second non-folding areas in a first direction, and the folding axis extends in a second direction crossing the first direction,
wherein the first and second support plates are spaced apart from each other in the first direction.

15. A method for manufacturing a display device, the method comprising:
preparing a display module which displays an image, wherein a folding area foldable with respect to a folding axis and first and second non-folding areas respectively adjacent to opposing sides of the folding area are defined in the display module on a plane;
disposing an adhesive layer on a lower surface of the display module;
forming an uneven pattern in a pattern area of the adhesive layer;
curing the pattern area of the adhesive layer; and
disposing first and second support plates, on a surface of the adhesive layer, to be spaced apart from each other,
wherein the pattern area of the adhesive layer overlaps the non-folding areas of the display module, and
a portion of the first support plate overlaps a first section of the pattern area, and a portion of the second support plate overlaps a second section of the pattern area.

16. The method of claim 15, wherein
when the display module is in an unfolded state, the folding area is disposed between the first and second non-folding areas in a first direction, and the folding axis extends in a second direction crossing the first direction,
wherein the first and second support plates are spaced apart from each other in the first direction.

17. The method of claim 15, wherein the adhesive layer comprises a thermosetting resin or a photocurable resin.

18. The method of claim 17, wherein
the adhesive layer comprises a first non-pattern area adjacent to a side of the pattern area and a second non-pattern area adjacent to an opposing side of the pattern area,
wherein the curing the pattern area of the adhesive layer comprises:
preparing first and second masks below the surface of the adhesive layer; and
irradiating the pattern area of the adhesive layer with light,
wherein the first mask is disposed to overlap the first non-pattern area, and the second mask is disposed to overlap the second non-pattern area.

19. The method of claim 15, wherein an adhesive strength of the pattern area after the curing of the pattern area is less than an adhesive strength of the first and second non-pattern areas.

20. The method of claim 15, wherein the display module comprises:
a display panel which displays an image; and
a protective film disposed on a lower surface of the display panel.
